(19) United States
(12) Patent Application Publication
(10) Pub. No.: US 2020/0395913 A1
(43) Pub. Date: Dec. 17, 2020

(54) PIEZOELECTRIC SUBSTRATE AND SURFACE ACOUSTIC WAVE DEVICE

(71) Applicant: KYOCERA Corporation, Kyoto-shi, Kyoto (JP)

(72) Inventors: Shuzo IWASHITA, Kirishima-shi, Kagoshima (JP); Shinji INOUE, Sagara-gun, Kyoto (JP); Hiroyuki YAMAJI, Kyoto-shi, Kyoto (JP); Hisao KONDOU, Higashiomi-shi, Shiga (JP)

(21) Appl. No.: 16/311,384

(22) PCT Filed: Jun. 29, 2018
(86) PCT No.: PCT/JP2018/024794

§ 371 Date: Dec. 19, 2018

(30) Foreign Application Priority Data
Jun. 29, 2017 (JP) 2017-127859

(51) Int. Cl. H03H 9/02; H01L 41/18

(52) U.S. Cl. CPC H03H 9/02559; H01L 41/18; H03H 9/02921

(57) ABSTRACT

There is provided a piezoelectric substrate including a lithium-containing metal compound crystal such as a lithium tantalate (LT) crystal, wherein potassium is contained in the substrate and the distribution of potassium is approximately uniform as observed in the direction of the thickness of the substrate. There is also provided a piezoelectric substrate, wherein a peak coming from Li—O lattice vibration and appearing around 380 cm⁻¹ is shifted to a high wave number side compared with that in an untreated piezoelectric substrate having a conductivity of 1×10⁻¹⁵ S/cm or less in Raman spectra measured from the cross section direction.

### TECHNICAL FIELD

The present invention relates to: a piezoelectric substrate which includes a lithium-containing metal compound crystal and can be used in use applications such as a surface acoustic wave (SAW) device that can perform a signal processing utilizing a SAW; and a SAW device equipped with the piezoelectric substrate.

### BACKGROUND ART

A piezoelectric substrate composed of a lithium-containing metal compound crystal has been widely used as a SAW device that can perform a signal processing utilizing electric properties of a SAW. As the lithium-containing metal compound crystal, a lithium tantalate LiTaO₃ (also referred to as LT, hereinafter) crystal can be used, for example. As the lithium-containing metal compound crystal, a lithium niobate LiNbO₃ crystal can also be used. A SAW device has such a structure that an electrode having a metallic pattern formed by a photolithographic method is formed on a piezoelectric substrate composed of a LT crystal or the like.

A piezoelectric substrate such as a LT substrate has characteristic properties including a high pyroelectric coefficient and high resistivity. Accordingly, a charge is likely to be generated on the surface as the result of a slight change in temperature, and the generated charge is accumulated and the charged state can be maintained until a charge elimination treatment is applied externally. Therefore, in the process for producing a substrate (wafer) from the single crystal, there is such a problem that cracking or chipping is likely to occur in the surface or edge of the substrate due to static discharge (spark) and consequently productivity may be deteriorated.

In the process of producing a surface acoustic wave device, there are several steps each accompanied by the change in temperature, such as the formation of an electrode thin film, the pre-bake or post-bake in photolithography and the like. Therefore, in the case where the above-mentioned LT single crystal or the like is used as a piezoelectric substrate, the generation of static electricity in the piezoelectric substrate becomes a problem in the process of producing a surface acoustic wave device. When a piezoelectric substrate is charged, electrostatic discharge occurs in the piezoelectric substrate, resulting in the cracking or breakage of the piezoelectric substrate. Furthermore, the formed electrode may short out by the action of the static electricity.

As a method for solving the problem associated with the discharge of a piezoelectric substrate, various methods whereby it becomes possible to increase the conductivity of the surface of the piezoelectric substrate have been proposed. By increasing the conductivity of the surface of a piezoelectric substrate, a charge generated on the surface of the piezoelectric substrate moves on the surface of the substrate to reduce the difference in potential on the surface of the substrate, thereby preventing the occurrence of a discharge phenomenon caused by the local accumulation of the charge.

Conventionally, as a method for increasing the conductivity of the surface of a piezoelectric substrate, a method has been proposed in which the piezoelectric substrate is subjected to a reduction treatment by a heat treatment (see, for example, Patent Documents 1 to 5).

### RELATED ART DOCUMENT

### Patent Document

Patent Document 1: Japanese Unexamined Patent Publication No. 11-92147

Patent Document 2: Japanese Patent No. 3816903

Patent Document 3: Japanese Unexamined Patent Publication No. 2010-173864

Patent Document 4: Japanese Patent No. 4937178

Patent Document 5: Japanese Patent No. 4789281

### SUMMARY OF THE INVENTION

A piezoelectric substrate according to an embodiment of the present invention includes a lithium-containing metal compound crystal, wherein potassium is contained in the substrate and the distribution of potassium is approximately uniform as observed in the direction of the thickness of the substrate. A piezoelectric substrate according to an embodiment of the present invention includes a lithium-containing metal compound crystal, wherein a peak coming from Li—O lattice vibration and appearing around 380 cm⁻¹ is shifted to a high wave number side compared with that in a piezoelectric substrate having a conductivity of 1×10⁻¹⁵ S/cm or more in Raman spectra measured from the cross section direction, or alternatively a peak coming from Li—O lattice vibration appears on a high wave number side relative to 381 cm⁻¹ in Raman spectra measured from the cross section direction. A surface acoustic wave device according to an embodiment of the present invention is provided with a piezoelectric substrate as mentioned above and an electrode formed on the surface of the piezoelectric substrate.

### BRIEF DESCRIPTION OF THE DRAWINGS

FIG. 1A shows an image illustrating the uniformity of potassium in a piezoelectric substrate produced in Example 1 as measured by TOF-SIMS.

FIG. 1B shows an image illustrating the uniformity of potassium in a piezoelectric substrate produced in Example 2 as measured by TOF-SIMS.

FIG. 1C shows an image illustrating the uniformity of potassium in a piezoelectric substrate produced in Example 3 as measured by TOF-SIMS.

FIG. 2A shows an image illustrating the uniformity of potassium in a piezoelectric substrate produced in Comparative Example 1 as measured by TOF-SIMS.

FIG. 2B shows an image illustrating the uniformity of potassium in a piezoelectric substrate produced in Comparative Example 2 as measured by TOF-SIMS.

FIG. 3 shows a graph illustrating one example of the result of the measurement of Raman spectra of a piezoelectric substrate.

### EMBODIMENTS FOR CARRYING OUT THE INVENTION

Hereinbelow, a piezoelectric substrate according to an embodiment of the present invention will be described in detail. In the following explanation, a LT crystal is used as a typical example of the lithium-containing metal compound crystal. Namely, the piezoelectric substrate according to the present embodiment includes a single crystal of LT, wherein potassium is contained in the substrate, and the distribution of potassium is approximately uniform as observed in the direction of the thickness of the substrate. Hereinbelow, a substrate composed of a single crystal of a LT crystal is sometimes simply referred to as a LT substrate.

The piezoelectric substrate can be produced by allowing a LT single crystal bar to grow by, for example, the Czochralski method and then slicing the LT single crystal bar. The thickness of the piezoelectric substrate is preferably about 0.3 to 1 mm inclusive, but is not limited thereto.

In general, the conductivity of a LT crystal varies depending on the concentration of oxygen voids in the crystal. When oxygen voids are formed in the LT crystal, the valency of some of Ta ions varies from 5+ to 4+, whereby electric conductivity can be developed. In the conventional methods (Patent Documents 1 to 5, etc.), it is attempted to improve the conductivity of a piezoelectric substrate by heat-treating the piezoelectric substrate under a reductive atmosphere to increase the concentration of oxygen voids in the piezoelectric substrate.

In a LT crystal, there are a relatively large number of lithium voids formed therein. When potassium ions penetrate into the lithium voids, the concentration of the voids decreases. As a result, Li—O lattice vibration shifts to a high wave number (high frequency) side, and accordingly the concentration of a carrier can be increased and the conductivity can also be increased. The piezoelectric substrate according to the present embodiment contains potassium therein, wherein the distribution of potassium is approximately uniform as observed in the direction of the thickness of the substrate. With respect to the state of potassium distributed in the substrate, it is not necessarily required that all of potassium components exist in the form of potassium ions.

In order to allow potassium to be distributed approximately uniformly as observed in the direction of the thickness of the substrate, the substrate is heat-treated at a temperature equal to or higher than 500° C. and equal to or lower than a Curie temperature in a nitrogen atmosphere together with a potassium salt, e.g., potassium hydrogen carbonate KHCO₃, preferably while placing the potassium salt in the vicinity of the substrate, for example. As the result of the heat treatment, a voltage due to pyrocharge generates on the surface of the substrate, and a molten Li or K carbonate salt generated on the surface of the substrate is converted to an electrolyte, resulting in the occurrence of a battery reaction between CO₂ and H₂O both generated as the result of the thermal decomposition of potassium hydrogen carbonate. For example, the diffusion and solid-solution of potassium in the substrate can be accelerated by the battery reaction. The potassium salt to be used may have any form selected from a paste-like form, a solution-like form and a solid-like form.

In the present embodiment, the distribution of solid-soluted potassium is approximately uniform as observed in the direction of the thickness of the substrate. The term “approximately uniform” as used herein refers to a state that, when potassium in the cross section of the piezoelectric substrate is analyzed by TOF-SIMS (time-of-flight secondary ion mass spectrometry), the CV value of the distribution of potassium in the direction of the thickness of the substrate which is obtained by the analysis of an image of potassium element mapping data is 0.7 or less, preferably 0.5 or less. A CV value refers to a coefficient of variation ((standard deviation σ)/(mean value)) of an area ratio of a potassium-detected part as measured by an image analysis, and a CV value of 0.7 or less means that the variation in the distribution of potassium is small. The method for determining the CV value will be described in detail in the section “EXAMPLES”. It is preferred that the distribution of potassium is also approximately uniform, i.e., has a CV value of 0.7 or less, preferably 0.5 or less, as observed in the direction of the planer direction as well as the thickness direction.

In the present embodiment, potassium is arranged in lithium voids in the LT crystal by solid-soluting potassium ions in the LT crystal. As a result, the concentration of voids in the substrate decreases, and Li—O lattice vibration shifts to a high wave number (high frequency) side. Namely, in the piezoelectric substrate according to the embodiment, a peak coming from Li—O lattice vibration and appearing around 380 cm⁻¹ is shifted to a high wave number side compared with that in a piezoelectric substrate having a conductivity of 1×10⁻¹⁵ S/cm or more in Raman spectra measured in the cross section direction. The term “cross section direction” as used herein refers to a direction orthogonal to the substrate cross section that intersects the main surface of the substrate. In the present embodiment, the Raman spectra as measured from the cross section direction are those obtained by irradiating a cross section (cleavage plane) appearing by the cleavage of the substrate with a laser beam for measurement use from the direction vertical to the cross section. In the present embodiment in which a LT crystal is used, (10-12) plane, for example, of the LT crystal appears in the substrate cross section (cleavage plane). The amount of the shift to a high wave number side is generally 1.0 cm⁻¹ or more, preferably 2 cm⁻¹ or more, and the upper limit of the amount of the shift is 6 cm⁻¹, preferably about 5 cm⁻¹.

The term “piezoelectric substrate having a conductivity of 1×10⁻¹⁵ S/cm or more” refers to, for example, a piezoelectric substrate having a low potassium concentration and non-uniform potassium distribution, i.e., having a CV value of more than 0.7.

A peak appearing around 380 cm⁻¹ corresponds to lithium (Li)-oxygen (O) lattice vibration. In the present embodiment, because potassium is solid-saluted within Li voids, the concentration of the Li voids decreases, and a peak coming from Li—O lattice vibration, i.e., a peak appearing around 380 cm⁻¹, is shifted to a high wave number side and is located on a high wave number side relative to 381 cm⁻¹.

As mentioned above, when a peak appearing around 380 cm⁻¹ is shifted to a high wave number side and is located on a high wave number side, the concentration of a carrier can increase and the conductivity can be improved. In the piezoelectric substrate according to the present embodiment, the conductivity is adjusted to 1×10⁻⁹ S/cm or less, preferably 1×10⁻¹⁰ S/cm or less, and 1×10⁻¹³ S/cm or more, preferably 1×10⁻¹² S/cm or more.

As mentioned above, in order to allow potassium to be distributed approximately uniformly as observed in the direction of the thickness of the substrate, potassium hydrogen carbonate is used and the substrate is heat-treated in a nitrogen atmosphere at a temperature equal to or lower than a Curie temperature.

Alternatively, it is also possible to increase the conductivity of the substrate by heat-treating the substrate under any one of various reductive atmospheres instead of allowing potassium to be contained/distributed in the substrate (Patent Documents 1 to 5, etc.). In this case, however, the treatment under a reductive atmosphere requires higher cost, the dangerous degree increases, and the treatment becomes complicated, resulting in the deterioration in work efficiency.

As mentioned above, in the piezoelectric substrate according to the present embodiment, because potassium penetrates in solid-solution or the like into lithium voids in the LT crystal through a heat treatment, potassium can be contained, the concentration of Li voids in the substrate is relatively low, and the lattice vibration is shifted to a high wave number (high frequency) side. Accordingly, the piezoelectric substrate according to the present embodiment has a relatively high carrier concentration and a relatively high conductivity. Furthermore, because potassium is distributed approximately uniformly as observed in the direction of the thickness of the substrate, the variation in conductivity is reduced among substrates as well as within the substrate and therefore the variation in properties of the substrate associated with the distribution of potassium in the substrate is also reduced.

Accordingly, pyrocharge generated in the piezoelectric substrate due to the change in temperature during the process of the production of the piezoelectric substrate or the production of a SAW device or the like can be released efficiently, the breakage caused by sparks or the like or the failure of devices can be reduced, and the variation in SAW speed during the formation of a SAW device (SAW filter) can also be reduced.

The piezoelectric substrate according to the present embodiment can be produced by heat-treating the substrate together with KHCO₃ in a nitrogen atmosphere at a temperature equal to or lower than a Curie temperature. Therefore, any complicated sample set for a treatment furnace is not needed unlike the conventional method. Furthermore, because it is not needed to introduce a reducing gas into the treatment furnace, the dangerous degree can be reduced and the increase in cost can also be reduced.

A SAW device according to the present embodiment is provided with a piezoelectric substrate as mentioned above and an electrode formed on the surface of the piezoelectric substrate, and can be used as a filter for extracting an electric signal having a specific frequency selectively. The electrode is generally a fine interdigitated array electrode, and can be produced by forming an electrode thin film made from an aluminum or the like on the surface of the piezoelectric substrate and then subjecting the electrode thin film to photolithography to form an electrode having a desired shape. More specifically, firstly an electrode thin film is formed on the surface of the piezoelectric substrate surface by a sputtering method or the like. Subsequently, an organic resin that serves as a photoresist is applied onto the electrode thin film and is then pre-baked under high-temperature conditions. Subsequently, the resultant product is exposed to light using a stepper or the like to perform the patterning of an electrode film. After the resultant product is post-baked under high-temperature conditions, the product is subjected to development to dissolve the photoresist. Finally, the product is subjected to wet- or dry-etching to form an electrode having a desired shape. The SAW device according to the present embodiment can be used suitably as a high-frequency filter or the like in a mobile communication typified by a mobile phone or a visual media device.

In the above-mentioned explanation, a LT substrate is mainly described. However, in a piezoelectric substrate composed of another lithium-containing metal compound crystal such as a lithium niobate (LN) single crystal, it also becomes possible to solid-solute and contain potassium approximately uniformly in the substrate as observed in the direction of the thickness of the substrate. As a result, it becomes possible to shift a peak appearing around 380 cm⁻¹ to a high wave number side compared with that in a piezoelectric substrate having a conductivity of 1×10⁻¹⁵ S/cm or more and therefore allow the peak to appear on a high wave number side relative to 381 cm⁻¹.

### EXAMPLES

Hereinbelow, one of embodiments will be described in more specifically with reference to examples. However, the present embodiment is not limited to these examples.

### Example 1

A LT single crystal bar having a diameter of about 100 mm was grown using lithium carbonate and tantalum pentoxide as raw materials by a Czochralski method. The LT single crystal bar was subjected to peripheral grinding, slicing and polishing to produce a substrate having a thickness of 200 μm. The substrate was heat-treated together with KHCO₃ under a nitrogen gas atmosphere at 550° C. for 2 hours to produce a LT substrate.

### Example 2

For the purpose of examining the acceptable degree of variation in a value of a physical property, a LT substrate was produced in the same manner as in Example 1.

### Example 3

A LT substrate was produced in the same manner as in Example 1, except that the treatment temperature was adjusted to 580° C.

### Comparative Example 1

A LT substrate was used, which was produced by applying a KCl solution onto a LT substrate, then sandwiching the LT substrate by LT substrates each strongly reduced in an reductive atmosphere, and then heat-treating the resultant produce in a reductive atmosphere.

### Comparative Example 2

A LT substrate was used, which was produced by allowing a LT substrate to coexist with a metal element (Al) and then heat-treating the resultant product under a reduced pressure.

### Evaluation of Potassium Uniformity

Potassium in a cross section of a LT substrate was measured by TOF-SIMS (TRIFT II I manufactured by ULVAC-PHI), and element mapping was performed. The conditions for the measurement are as follows.

Primary ion: ¹⁹⁷Au₁ cluster ion

Primary ion current value: 900 pA (aperture: 3)

Measurement region: about 300-μm square region

Measurement time: 15 minutes (mapping analysis)

Subsequently, the element mapping image was subjected to a 8-bit grayscale processing (256 gray levels), and was then binarized. With respect to nine regions in total, including arbitrary three regions in each of a front surface part, a center part and a rear surface part, in the cross section of the substrate, an image processing of a potassium-detected area was carried out, wherein the area of image in each region was 50 pixels×50 pixels. As an image processing software, image-J was used.

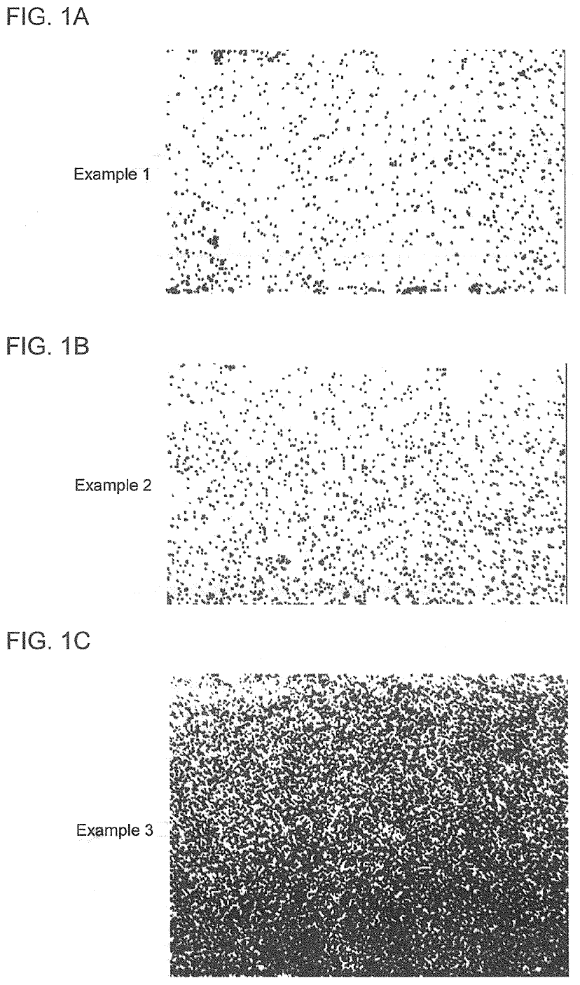

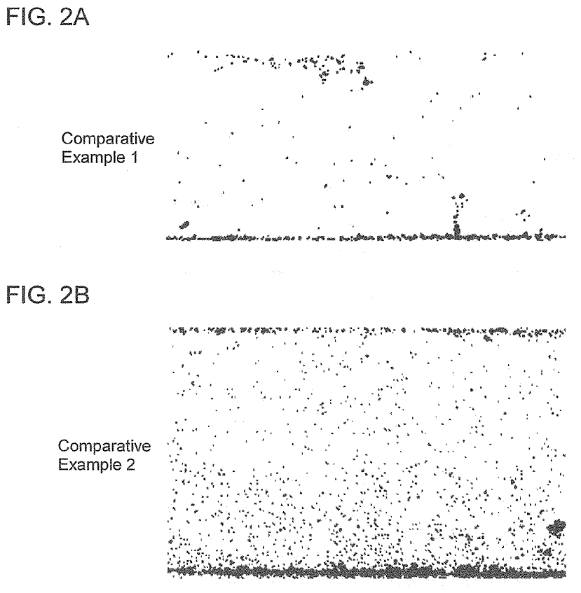

The measurement results on the LT substrates produced in Examples 1 to 3 are shown in FIGS. 1A to 1C, respectively. The measurement results on the LT substrates produced in Comparative Examples 1 and 2 are shown in FIGS. 2A and 2B, respectively. In each of the drawings, a black dot indicates the presence of potassium. Each of the drawings is an image of one representative region among the nine regions.

A coefficient of variation, i.e., a CV value, ((standard deviation σ)/(mean value)), of the area ratios was determined from the potassium area ratios obtained with respect to all of the nine regions. The results are shown in Table 1.

TABLE 1

| | Mean value Ave | Standard | CV value |
|---|---|---|---|
| | (unit: (pixel)²) | deviation (σ) | (σ/Ave) |
| Example 1 | 15.95 | 6.06 | 0.38 |
| Example 2 | 20.29 | 9.13 | 0.45 |
| Example 3 | 173.52 | 39.91 | 0.23 |
| Comparative | 10.83 | 11.37 | 1.05 |
| Example 1 | | | |
| Comparative | 26.92 | 26.92 | 1.00 |
| Example 2 | | | |

### Raman Spectra of Piezoelectric Substrate

### (a) Measurement Samples

With respect to each of LT substrates of sample Nos. 1 to 14 shown in Table 2, Raman spectra from the direction of the substrate cross section were measured by Raman spectroscopy. In Table 2, sample Nos. 1 to 3 correspond to the piezoelectric substrates produced in Examples 1 to 3, respectively. Sample Nos. 13 and 14 correspond to the piezoelectric substrates produced in Comparative Examples 1 and 2, respectively. The LT substrates of sample Nos. 5 to 12 correspond to piezoelectric substrates which were produced in the same manner as in Example 1, except that the treatment temperatures were altered to the temperatures shown in Table 2.

### (b) Measurement of Raman Spectra

Each of the piezoelectric substrates of the above-mentioned samples was subjected to the measurement of Raman spectra in an arbitrary region using a laser Raman spectroscopic measurement device (HR-800 manufactured by HORIBA, Ltd., laser wavelength: 514.77 mm, grating: 600 lines, objective lens: ×100, room temperature), wherein the arbitrary region was 1 mm apart from the outer peripheral side surface of the substrate and the measurement was carried out from the substrate cross section direction.

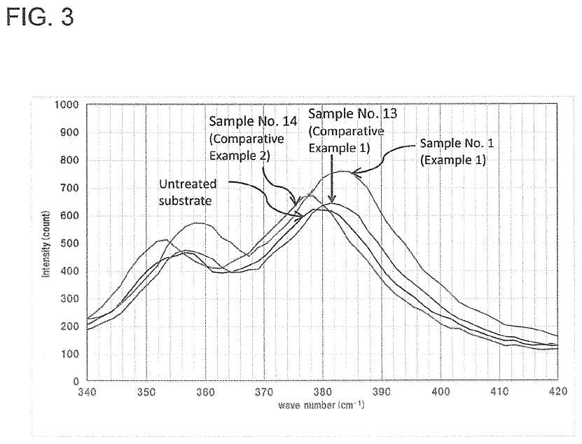

FIG. 3 shows Raman profiles shown in sample No. 1 (Example 1), sample No. 13 (Comparative Example 1) and sample No. 14 (Comparative Example 2). The Raman profile of the substrate of sample No. 1 (Example 1) before the heat treatment which was measured in the same manner is also shown in FIG. 3.

As shown in FIG. 3, it was demonstrated that, in sample No. 1 (Example 1), a peak appearing around 380 cm⁻¹ was shifted to a high wave number side compared with peaks for an untreated substrate having a conductivity of 1×10⁻or more and the substrate No. 13 (Comparative Example 1) and the substrate No. 14 (Comparative Example 2), thereby located on a high wave number side relative to 380 cm⁻¹.

### (c) Properties of LT Substrates of Sample Nos. 1 to 14

The value of a peak appearing around 380 cm⁻¹ in Raman spectra, the potassium uniformity (CV value), the conductivity and the crystal phase of each of the LT substrates of sample Nos. 1 to 14 are shown in Table 2. The potassium uniformity (CV value) was measured by the above-mentioned method. The conductivity was measured by a three-terminal method under the application of a voltage of 500 V at a temperature of 25° C. and a humidity of 50% using DSM-8103 manufactured by TOA Corporation.

TABLE 2

| | | Treatment | Raman | K | | |
|---|---|---|---|---|---|---|
| | | temperature | shift | uniformity | Conductivity | Crystal |
| | No. | (° C.) | (cm⁻¹) | (CV value) | (S/cm) | phase |
| | 1 | 550 | 384 | 0.38 | 1.0E−12 | LiTaO₃ |
| | 2 | 550 | 384 | 0.45 | 2.0E−12 | LiTaO₃ |
| | 3 | 580 | 384 | 0.23 | 1.2E−11 | LiTaO₃ |
| | 4 | 510 | 383 | 1.00 | 6.0E−14 | LiTaO₃ |
| | 5 | 520 | 383 | 0.67 | 1.0E−13 | LiTaO₃ |
| | 6 | 535 | 384 | 0.50 | 6.0E−13 | LiTaO₃ |
| | 7 | 555 | 385 | 0.33 | 5.0E−12 | LiTaO₃ |
| | 8 | 560 | 385 | 0.30 | 7.0E−12 | LiTaO₃ |
| | 9 | 570 | 385 | 0.18 | 1.0E−11 | LiTaO₃ |
| | 10 | 575 | 385 | 0.09 | 1.0E−10 | LiTaO₃ |
| | 11 | 585 | 386 | 0.07 | 1.0E−09 | LiTaO₃ |
| | 12 | 590 | 386 | 0.05 | 3.0E−09 | LiTaO₃ |
| [symbol] | 13 | 570 | 381 | 1.05 | 2.8E−11 | LiTaO₃ |
| [symbol] | 14 | 570 | 378 | 1.00 | 6.4E−12 | LiTaO₃ |

[symbol]

Comparative examples

As shown in Table 2, each of the piezoelectric substrates of sample Nos. 1 to 12 had good potassium uniformity in the substrate (wafer), and therefore had a small variation in conductivity in the substrate and a high conductivity. Therefore, these piezoelectric substrates can be used suitably as element materials for SAW devices.

1. A piezoelectric substrate comprising a lithium-containing metal compound crystal, wherein potassium is contained in the substrate and the distribution of potassium is approximately uniform as observed in the direction of the thickness of the substrate.

2. The piezoelectric substrate according to claim 1, wherein the CV value of the distribution of potassium as determined in the direction of the thickness is 0.7 or less.

3. A piezoelectric substrate comprising a lithium-containing metal compound crystal, wherein, in Raman spectra measured from the cross section direction, a peak coming from Li—O lattice vibration and appearing around 380 cm⁻¹ is shifted to a high wave number side compared with that in a piezoelectric substrate having a conductivity of 1×10⁻¹⁵ S/cm or more.

4. A piezoelectric substrate comprising a lithium-containing metal compound crystal, wherein, in Raman spectra measured from the cross section direction, a peak coming from Li—O lattice vibration appears on a high wave number side relative to 381 cm⁻¹.

5. The piezoelectric substrate according to claim 1, wherein the conductivity is 1×10⁻⁹ to 1×10⁻¹³ S/cm.

6. The piezoelectric substrate according to claim 3, wherein, in Raman spectra measured from the cross section direction, a peak appearing around 380 cm⁻¹ is shifted by 1 cm⁻¹ or more to a high wave number side compared with that in a piezoelectric substrate having a conductivity of 1×10⁻¹⁵ S/cm or more.

7. The piezoelectric substrate according to claim 1, wherein the piezoelectric substrate comprises a single crystal of a lithium-containing metal compound crystal.

8. The piezoelectric substrate according to claim 1, wherein the metal compound is lithium tantalate.

9. The piezoelectric substrate according to claim 1, wherein the metal compound is lithium niobate.

10. A surface acoustic wave device comprising a piezoelectric substrate as recited in claim 1 and an electrode formed on the surface of the piezoelectric substrate.

11. The piezoelectric substrate according to claim 3, wherein the conductivity is 1×10⁻⁹ to 1×10⁻¹³ S/cm.

12. The piezoelectric substrate according to claim 4, wherein the conductivity is 1×10⁻⁹ to 1×10⁻¹³ S/cm.

13. The piezoelectric substrate according to claim 4, wherein, in Raman spectra measured from the cross section direction, a peak appearing around 380 cm⁻¹ is shifted by 1 cm⁻¹ or more to a high wave number side compared with that in a piezoelectric substrate having a conductivity of 1×10⁻¹⁵ S/cm or more.

14. The piezoelectric substrate according to claim 3, wherein the piezoelectric substrate comprises a single crystal of a lithium-containing metal compound crystal.

15. The piezoelectric substrate according to claim 4, wherein the piezoelectric substrate comprises a single crystal of a lithium-containing metal compound crystal.
